(19) United States
(12) Patent Application Publication
(10) Pub. No.: US 2025/0309176 A1
(43) Pub. Date: Oct. 2, 2025

(54) BONDING LAYERS IN SEMICONDUCTOR PACKAGES AND METHODS OF FORMING

(71) Applicant: Taiwan Semiconductor Manufacturing Co., Ltd., Hsinchu (TW)

(72) Inventors: Chen-Hua Yu, Hsinchu (TW); Tung-Liang Shao, Hsinchu (TW)

(21) Appl. No.: 19/238,716

(22) Filed: Jun. 16, 2025

Related U.S. Application Data
(63) Continuation of application No. 18/512,710, filed on Nov. 17, 2023.
(60) Provisional application No. 63/516,595, filed on Jul. 31, 2023.
(60) Provisional application No. 63/518,133, filed on Aug. 8, 2023.

(51) Int. Cl. H01L 23/00; H01L 21/48; H01L 25/00; H01L 25/065; H01L 25/16

(52) U.S. Cl. CPC H01L 24/29; H01L 21/4857; H01L 24/05; H01L 24/08; H01L 24/27; H01L 24/32; H01L 24/80; H01L 24/83; H01L 25/0657; H01L 25/16; H01L 25/50; H01L 24/73; H01L 2224/05572; H01L 2224/05624; H01L 2224/05647; H01L 2224/08145; H01L 2224/27845; H01L 2224/29082; H01L 2224/29083; H01L 2224/29187; H01L 2224/29188; H01L 2224/73253; H01L 2224/80009; H01L 2224/8001; H01L 2224/80357; H01L 2224/80379; H01L 2224/80896; H01L 2224/8301; H01L 2224/83896; H01L 2225/06541; H01L 2924/05432; H01L 2924/05442; H01L 2924/059

(57) ABSTRACT

A semiconductor device comprising a first semiconductor component and a composite bonding layer on the first semiconductor component. The composite bonding layer comprises a dielectric stress buffer layer and a dielectric planarization layer, wherein a hardness of the dielectric stress buffer layer is greater than a hardness of the dielectric planarization layer. The semiconductor device further includes a second semiconductor component bonded to the first semiconductor component by insulator-to-insulator bonding between the composite bonding layer and an insulating bonding layer on the second semiconductor component, wherein the dielectric planarization layer is disposed an interface between the composite bonding layer and the insulating bonding layer.

### PRIORITY CLAIM AND CROSS-REFERENCE

This application is a continuation of U.S. patent application Ser. No. 18/512,710, filed Nov. 17, 2023, which application claims the benefit of U.S. Provisional Application No. 63/518,133, filed on Aug. 8, 2023, and further claims the benefit of U.S. Provisional Application No. 63/516,595, filed on Jul. 31, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a POP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2A, 2B, 3A, and 3B illustrate intermediate stages of manufacturing a bonding layer in accordance with some embodiments.

FIGS. 4, 5A, 5B, 6A, and 6B illustrate intermediate stages of manufacturing a semiconductor device in accordance with some embodiments.

FIGS. 7 through 10, 11A, 11B, and 12 through 14 illustrate intermediate stages of manufacturing a semiconductor device in accordance with some embodiments.

FIGS. 15 through 18 illustrate intermediate stages of manufacturing a semiconductor device in accordance with some embodiments.

FIGS. 19 through 25 illustrate intermediate stages of manufacturing a semiconductor device in accordance with some embodiments.

FIGS. 26 through 30 illustrate intermediate stages of manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a composite, insulating bonding layer for bonding two semiconductor components together. In some embodiments, the semiconductor components include a semiconductor die that is directly bonded to a support substrate or a heat dissipation feature with the composite bonding layer in an insulator-to-insulator bonding process. In some embodiments, the semiconductor components include two semiconductor dies that are directly bonded together with the composite bonding layer in an insulator-to-insulator and metal-to-metal bonding process. In some embodiments, the semiconductor components include a passive device die or a local silicon interconnect (LSI) die that is attached to a carrier substrate with the composite bonding layer in an insulator-to-insulator bonding process. The bonding of other types of package components with the composite bonding layer is also contemplated.

The composite, insulating bonding layer includes at least two dielectric layers: a stress buffer layer made of a relatively hard material and a planarization layer made of a relatively soft material. The stress buffer layer made of the relatively hard material helps absorb mechanical stress to improve mechanical integrity and reduce manufacturing defects in the bonded structure. The planarization layer is made of a relatively soft material, which is more conducive to achieving a high degree of planarity with a planarization process (e.g., chemical mechanical polish (CMP)). As a result, the composite bonding layer can achieve improved planarity with a softer, planarization layer while still having stress relief in the harder, stress buffer layer.

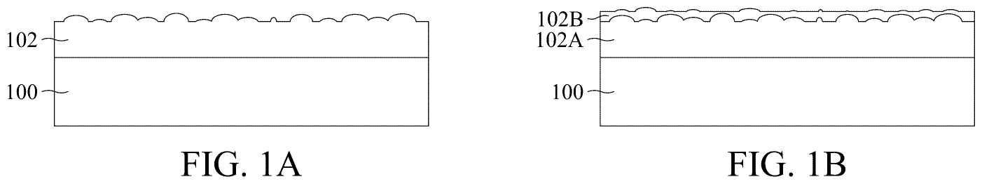

FIGS. 1A through 3B illustrate various intermediate steps of manufacturing a composite bonding layer in accordance with some embodiments. In FIGS. 1A and 1B, a carrier substrate 100 is provided. The carrier substrate 100 may be a glass carrier substrate, a ceramic carrier substrate, a wafer (e.g., a silicon wafer), or the like. The carrier substrate 100 maybe free of any devices, including free of any active or passive devices. In the completed semiconductor device, the carrier substrate 100 may provide structural support, and the carrier substrate 100 may also be referred to as a support substrate 100.

A dielectric stress buffer layer 102 is deposited on the carrier substrate 100. The dielectric stress buffer layer 102 may comprise silicon, oxygen, nitrogen, carbon, aluminum, boron, combinations thereof, or the like. For example, the dielectric stress buffer layer 102 comprises polyimide, silicone, silicon oxide, a nitride, a carbide, combinations thereof, or the like. The dielectric stress buffer layer 102 may be deposited by any suitable process, such as physical vapor deposition (PVD), chemical vapor deposition (CVD), atomic layer deposition (ALD), or the like. The dielectric stress buffer layer 102 may be made of a relatively hard material that can absorb stress in the bonded structure.

In various embodiments, a desired hardness for the dielectric stress buffer layer 102 can be achieved by tuning the deposition parameters and/or atomic composition of the dielectric stress buffer layer 102 to achieve a desired crystallization in the dielectric stress buffer layer 102. For example, more crystalline materials have been observed to be harder than more amorphous materials. In some embodiments, the deposition temperature for depositing the dielectric stress buffer layer 102 may be sufficiently high to form a polycrystalline layer with sufficient crystallization to provide the desired hardness. As another example, when the dielectric stress buffer layer 102 comprises particular elements (e.g., carbon), the deposition temperature for depositing the dielectric stress buffer layer 102 may be sufficiently high to form a compound with a sufficiently high quantity of sp² hybridization atoms (e.g., sp² carbon atoms) to provide the desired hardness. In some embodiments, a deposition temperature for depositing the dielectric stress buffer layer 102 may be in a range of 200° C. to 1200° C. In some embodiments, an atomic ratio of elements (e.g., silicon, oxygen, nitrogen, or the like) may be adjusted in the dielectric stress buffer layer 102 to achieve the desired hardness. For example, it has been observed that by increasing the carbon (C) concentration of the dielectric stress buffer layer 102, hardness of the dielectric stress buffer layer 102 can be desirably increased.

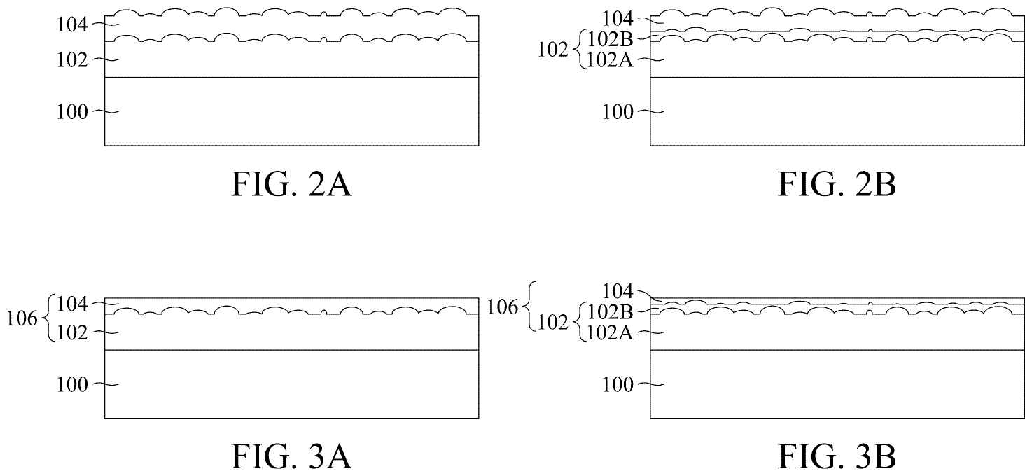

In some embodiments, the dielectric stress buffer layer 102 is a single, monolithic layer having a same material composition throughout as illustrated by FIG. 1A. In other embodiments, the dielectric stress buffer layer 102 has a multi-layer structure comprising at least two layers. For example, FIG. 1B illustrates embodiments where the dielectric stress buffer layer 102 has a multi-layer structure including a dielectric base layer 102A and an interfacial layer 102B. Each of layers (e.g., layer 102A and 102B) of the dielectric stress buffer layer 102 may be relatively hard and have the material properties of a single dielectric stress buffer layer 102 described above. However, the interfacial layer 102B may be softer than the dielectric base layer 102A. For example, the interfacial layer 102B may have a different crystallization and be more amorphous than the dielectric base layer 102A. As another example, the dielectric base layer 102A and the interfacial layer 102B may be made of a same material compound with different atomic ratios. For example, the dielectric base layer 102A may be made of silicon dioxide (SiO₂) while the interfacial layer 102B comprises silicon oxide with a different atomic ratio of oxygen (e.g., SiOₓ where x≠2). The interfacial layer 102B may be used to improve adhesion with a subsequently deposited planarization layer (see FIG. 2B). Although FIG. 1B illustrates the dielectric stress buffer layer 102 as having a bi-layer structure, it should be appreciated that the dielectric stress buffer layer 102 may have any number of layers with varying amounts of hardness (e.g., crystallization and/or atomic ratios).

In FIGS. 2A and 2B, a dielectric planarization layer 104 is deposited over the dielectric stress buffer layer 102. FIG. 2A corresponds to the embodiments of FIG. 1A where the dielectric stress buffer layer 102 is a monolithic material. FIG. 2B corresponds to the embodiments of FIG. 1B where the dielectric stress buffer layer 102 has a multi-layer structure.

The dielectric planarization layer 104 may comprise silicon, oxygen, nitrogen, carbon, aluminum, combinations thereof, or the like. In some embodiments, the dielectric planarization layer 104 comprises silicon oxide (e.g., SiOₓ), silicon carbonitride, silicon oxynitride, aluminum oxide (e.g., Al₂O₃), or the like. A thickness of the dielectric planarization layer 104 may be about 1% to about 20% of a thickness of the dielectric stress buffer layer 102. The dielectric planarization layer 104 may be deposited by any suitable process, such as PVD, CVD, ALD, or the like.

The dielectric planarization layer 104 has a different composition and be less hard than the dielectric stress buffer layer 102. Specifically, the dielectric planarization layer 104 may be made of a relatively soft material that is more conducive to planarization (e.g., CMP) than the dielectric stress buffer layer 102. For example, the dielectric planarization layer 104 may have a hardness less than 8 Mohs, which allows the dielectric planarization layer 104 to be planarized to a sufficiently high degree of planarity so that the dielectric planarization layer 104 can be subsequently bonded in an insulator-to-insulator bonding process. In some embodiments, a ratio of the hardness of the dielectric stress buffer layer 102 to the hardness of the dielectric planarization layer 104 may be in a range of 10:7 to 10:8. It has been observed that when the relative hardness of the dielectric stress buffer layer 102 and the dielectric planarization layer 104 is in the above range, the resulting composite bonding layer can be planarized to a high degree of planarity while still allowing for sufficient stress absorption. Further, the dielectric planarization layer 104 may have a lower surface roughness than the dielectric stress buffer layer 102. For example, a ratio of the surface roughness of the dielectric stress buffer layer to the surface roughness of the dielectric planarization layer 104 may be 10:7 or less.

In various embodiments, a desired low hardness for the dielectric planarization layer 104 can be achieved by tuning the deposition parameters and/or atomic composition of the dielectric planarization layer 104 to achieve a desired crystallization in the dielectric planarization layer 104. For example, more crystalline materials have been observed to be harder than more amorphous materials. As such, in some embodiments, the dielectric planarization layer 104 may be more amorphous than the dielectric stress buffer layer 102. In some embodiments, the deposition temperature for depositing the dielectric planarization layer 104 may be sufficiently low to form an amorphous layer with sufficiently low crystallization to provide the desired low hardness. As another example, when the dielectric planarization layer 104 comprises a particular element (e.g., carbon), the deposition temperature for depositing the dielectric planarization layer 104 may be sufficiently low to form a compound with a sufficiently high quantity of sp³ hybridization atoms (e.g., carbon atoms) to provide the desired hardness. For example, it has been observed that a larger quantity of sp² hybridization atoms results in a harder material whereas a larger quantity of sp³ hybridization atoms results in a softer material. In some embodiments, the dielectric stress buffer layer 102 has a higher quantity of sp² hybridization carbon than the dielectric planarization layer 104, and the dielectric planarization layer 104 has a higher quantity of sp³ hybridization carbon than the dielectric stress buffer layer 102. In some embodiments, the deposition temperature of the dielectric planarization layer 104 is less than the deposition temperature of the dielectric stress buffer layer 102. For example, a deposition temperature for depositing the dielectric planarization layer 104 may be in a range of 200° C. to 400° C. In some embodiments, an atomic ratio of elements (e.g., silicon, oxygen, nitrogen, or the like) may be adjusted in the dielectric planarization layer 104 to achieve the low desired hardness. For example, it has been observed that by increasing the oxygen (O) concentration of the dielectric planarization layer 104, hardness of the dielectric planarization layer 104 can be desirably decreased.

In embodiments where the dielectric stress buffer layer 102 has a multi-layer structure (see FIG. 2B), the interfacial layer 102B may be disposed between the dielectric base layer 102A and the dielectric planarization layer 104. The interfacial layer 102B may have a hardness between the dielectric base layer 102A and the dielectric planarization layer 104. For example, the interfacial layer 102B may be harder than the dielectric planarization layer 104 but less hard than the dielectric base layer 102A. This can be achieved by adjusting the relative crystallizations and/or atomic ratios of the dielectric base layer 102A, the interfacial layer 102B, and the dielectric planarization layer 104. For example, the interfacial layer 102B may be more crystalline than the dielectric planarization layer 104 and more amorphous than the dielectric base layer 102A. As another example, the atomic ratios of the interfacial layer 102B may be between the dielectric planarization layer 104 and the dielectric base layer 102A. For example, the dielectric layer 102A may be made of silicon dioxide (SiO₂), the interfacial layer may be made of SiOₓ, and the dielectric planarization layer 104 may be made of SiO_{y}, where x is a number between y and 2. In this manner, the interfacial layer 102B may improve adhesion between the dielectric base layer 102A and the dielectric planarization layer 104.

In FIGS. 3A and 3B, a planarization process (e.g., a CMP or the like) is performed on the dielectric planarization layer 104, thereby forming a composite bonding layer 106. The composite bonding layer 106 includes the dielectric stress buffer layer 102 and the dielectric planarization layer 104. Due to the relative softness of the dielectric planarization layer 104 compared to the dielectric stress buffer layer 102, the dielectric planarization layer 104 can be easily planarized to a high degree of planarity. For example, the top surface of the dielectric planarization layer 104 has a higher degree of planarity than the top surface of the dielectric stress buffer layer 102 (e.g., the interface between the dielectric planarization layer 104 and the dielectric stress buffer layer 102). As a result, the composite bonding layer 106 has a planar bonding surface, which can be used to bond the carrier substrate 100 to another semiconductor components. FIG. 3A illustrates embodiments corresponding to FIG. 1A where the dielectric stress buffer layer 102 has a monolithic structure, and FIG. 3B illustrates embodiments corresponding to FIG. 1B where the dielectric stress buffer layer 102 has a multi-layer structure.

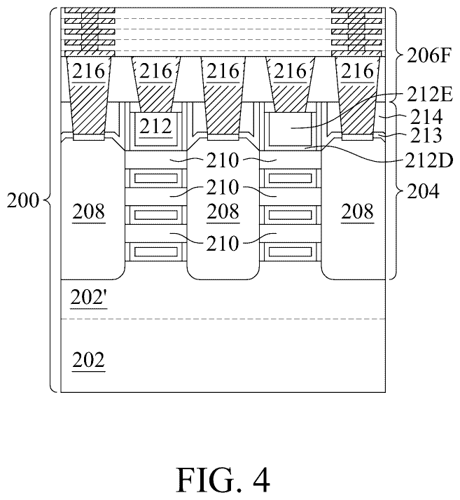

FIGS. 4 through 6B illustrates exemplary details of intermediate processing steps for bonding the carrier substrate 100 to an integrated circuit die 200 using an embodiment composite bonding layer 106. Referring first to FIG. 4, the integrated circuit die 200 includes a semiconductor substrate 202, such as silicon, doped or undoped, or an active layer of a semiconductor-on-insulator (SOI) substrate. The semiconductor substrate 202 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 202 has an active surface (e.g., the surface facing upwards in FIG. 4), sometimes called a front-side, and an inactive surface (e.g., the surface facing downwards in FIG. 4), sometimes called a backside.

A device layer 204 is formed at the front-side (i.e., the active surface) of the semiconductor substrate 202. The device layer 204 may include active devices (e.g., transistors, diodes, etc.), capacitors, resistors, etc. In some embodiments, the active devices of the device layer 204 includes nano-FETs (e.g., nanowire field effect transistors (FETs), nanosheet FETs (Nano-FETs), or the like). The nano-FETs comprise nanostructures 210 (e.g., nanosheets, nanowire, or the like) over fins 202′ that extend upwards from the base substrate 202, and the nanostructures 210 act as channel regions for the nano-FETs. The nanostructures 210 may include p-type nanostructures, n-type nanostructures, or a combination thereof.

Gate stacks 212 (including gate dielectric layers 212D and gate electrodes 212E) are disposed over top surfaces of the fins 202′ and along top surfaces, sidewalls, and bottom surfaces of the nanostructures 210. The gate dielectric layers 212D may be disposed between the gate electrodes 212E and the nanostructures 210. Epitaxial source/drain regions 208 are disposed on the fins 202′ on opposing sides of the gate stacks 212, and the nanostructures 210 may extend between adjacent epitaxial source/drain regions 208. Source/drain region(s) 208 may refer to a source or a drain, individually or collectively dependent upon the context. The device layer 204 may include other types of transistors (e.g., fin field effect transistors (FinFETs) or the like) as well.

An inter-layer dielectric (ILD) 214 is formed over the front-side of the semiconductor substrate 202. The ILD 214 surrounds and covers the devices of the device layer 204. The ILD 214 may include one or more dielectric layers formed of materials such as silicon oxide, silicon oxynitride, silicon oxycarbonitiride, Phospho-Silicate Glass (PSG), Boro-Silicate Glass (BSG), Boron-Doped Phospho-Silicate Glass (BPSG), undoped Silicate Glass (USG), or the like. The ILD 214 may be deposited by CVD, ALD, PVD, or the like. In some embodiments, a contact etch stop layer (CESL) 213, comprising silicon nitride or the like, may be disposed between the ILD 214 and the devices of the device layer 204.

Conductive plugs 216 extend through the ILD 214 and the CESL 213 to electrically and physically couple the devices of the device layer 204. For example, the conductive plugs 216 may couple the gate stacks 212 and source/drain regions 208. In some embodiments, silicide regions may be disposed at the interfaces between the conductive plugs 216 and the source/drain regions 208. The conductive plugs 216 may be formed of tungsten, cobalt, nickel, copper, silver, gold, aluminum, the like, or combinations thereof. Because the conductive plugs 216 are disposed on the front-side of the substrate 202, they may also be referred to as front-side contacts 216.

A front-side interconnect structure 206F is disposed over the ILD 214 and conductive plugs 216. The interconnect structure 206F interconnects the devices of the device layer 204 to form integrated circuits. The interconnect structure 206F includes, for example, metallization patterns in one or more dielectric layers. The metallization patterns include metal lines and vias formed in one or more low-k dielectric layers with damascene processes, for example. The metallization patterns of the interconnect structure 206F are electrically coupled to the devices of the device layer 204 by the conductive plugs 216.

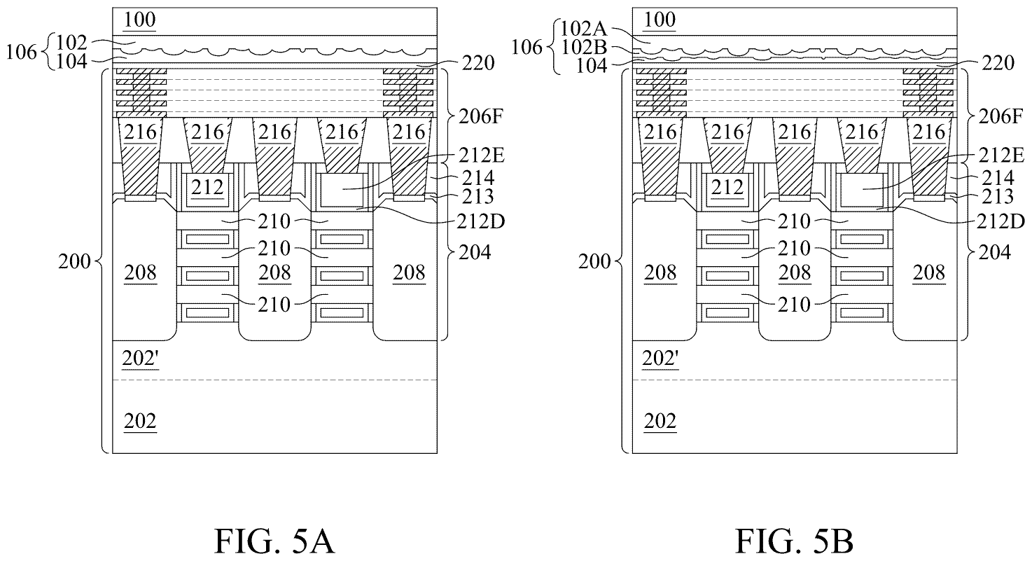

In FIGS. 5A and 5B, a first semiconductor component (e.g., the carrier substrate 100) is bonded to a second semiconductor component (e.g., the integrated circuit die 200) by the composite bonding layer 106 and an insulating bonding layer 220. For example, the carrier substrate 100 may be bonded to a top surface of the front-side interconnect structure 206F. The composite bonding layer 106 includes a harder, stress buffer layer 102 and a softer, planarization layer 104 as described above in FIGS. 1A through 3B. FIG. 5A illustrates embodiments where the stress buffer layer 102 has a monolithic structure, and FIG. 5B illustrates embodiments where the stress buffer layer 102 has a multi-layer structure that includes a dielectric base layer 102A and an interfacial layer 102B.

The insulating bonding layer 220 may be deposited on the front-side interconnect structure 206F by any suitable process, such as PVD, CVD, ALD, or the like. The bonding layer 220 may comprise an insulating material that is suitable for an insulator-to-insulator bonding process. Example materials for the bonding layer 220 include silicon oxide (e.g., SiO₂), silicon nitride, silicon oxynitride, silicon carbonitride, silicon oxycarbonitride, or the like.

After the composite bonding layer 106 and the bonding layer 220 are deposited, the carrier substrate 100 may be bonded to the front-side interconnect structure 206F using a suitable technique, such as insulator-to-insulator bonding (also referred to as dielectric-to-dielectric bonding), or the like. The insulator-to-insulator bonding process may include applying a surface treatment to one or more of the composite bonding layer 106 and the insulating bonding layer 220. The surface treatment may include a plasma treatment, which may be applied to an exposed surface of the respective bonding layer (e.g., a surface of the planarization layer 104 and/or a surface of the bonding layer 220). The plasma treatment may be performed in a vacuum environment. After the plasma treatment, the surface treatment may further include a cleaning process (e.g., a rinse with deionized water or the like) that may be applied to one or more of the composite bonding layer 106 and the insulating bonding layer 220. The carrier substrate 100 is then aligned with the front-side interconnect structure 206F and the two are pressed against each other to initiate a pre-bonding of the carrier substrate 100 to the front-side interconnect structure 206F. The pre-bonding may be performed at room temperature (e.g., between about 21° C. and about 25° C.). After the pre-bonding, an annealing process may be applied by, for example, heating the front-side interconnect structure 206F and the carrier substrate 100 to a temperature of in a range of 150° C. to 500° C. The annealing process increases bond strength and triggers the formation of covalent bonds between the composite bonding layer 106 and the insulating bonding layer 220, such as between the planarization layer 104 and the insulating bonding layer 220. Other bonding processes, such as ambient bonding, vacuum bonding, or the like may be used in other embodiments.

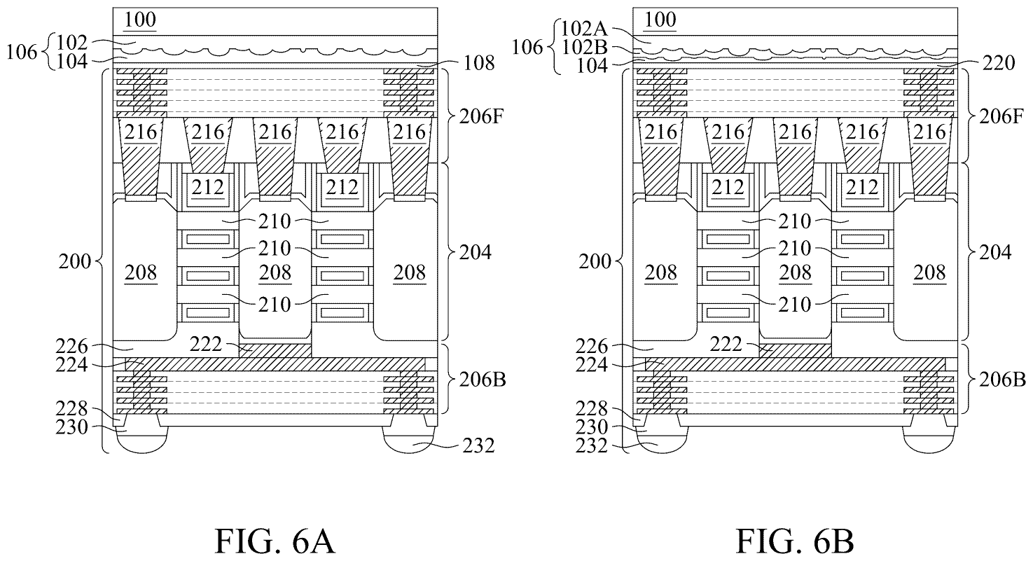

In FIGS. 6A and 6B, the substrate 202 and the fins 202′ of the integrated circuit die 200 are at least substantially replaced with a backside interconnect structure 206B. FIG. 6A illustrates embodiments where the stress buffer layer 102 has a monolithic structure, and FIG. 6B illustrates embodiments where the stress buffer layer 102 has a multi-layer structure that includes a dielectric base layer 102A and an interfacial layer 102B.

The substrate 202 and the fins 202′ may be substantially removed from the backside of the device layer 204 using one or more planarization processes (e.g., a chemical mechanical polish (CMP), or the like) and etch back processes. The etch back processes may be selective processes that etches the material of the substrate 202 and the fins 202′ at a faster rate than a material of the gate stacks 212 or the epitaxial source/drain regions 208. In some embodiments, sacrificial masking layers may be formed as part of forming the device layer 204 to aid in the selective removal of the substrate 202 and the fins 202′. In the illustrated embodiments, the substrate 202 and the fins 202′ are completely removed. In other embodiments, a small portion of the substrate 202 and/or the fins 202′ may remain.

After the substrate 202 and the fins 202′ are substantially removed, a backside ILD 226 is deposited on the backside of the device layer 204. The backside ILD 226 may include one or more dielectric layers formed of materials such as silicon oxide, silicon oxynitride, silicon oxycarbonitiride, Phospho-Silicate Glass (PSG), Boro-Silicate Glass (BSG), Boron-Doped Phospho-Silicate Glass (BPSG), undoped Silicate Glass (USG), or the like. Backside conductive plugs 222 extend through the backside ILD 226 to electrically and physically couple the epitaxial source/drain regions 208. In some embodiments, silicide regions may be disposed at the interfaces between the conductive plugs 222 and the source/drain regions 208. The backside conductive plugs 222 may be formed of tungsten, cobalt, nickel, copper, silver, gold, aluminum, the like, or combinations thereof. The backside conductive plugs 222 allow for additional connections to be made to a backside of the device layer 204 for increased routing flexibility.

A backside interconnect structure 206B is formed over the ILD 226 and conductive plugs 222 on the backside of the device layer 204. The backside structure 206B may include, for example, metallization patterns in one or more dielectric layers. The metallization patterns include metal lines and vias formed in one or more low-k dielectric layers with damascene processes, for example. Specifically, the backside interconnect structure 206B may provide power delivery circuits to the devices of the device layer 204. For example, the backside interconnect structure 206B may include a power rail 224 (sometimes referred to as a backside power rail, super power rail, or the like) to provide power to the transistors of the device layer 204. Because the power rail 224 may be larger (e.g., wider and/or thicker) than signal lines of the front-side interconnect structure 206F, locating the power rail 224 in the backside interconnect structure 206B improves routing flexibility and allows for additional signal lines to be formed in the frontside interconnect structure 206F.

The backside interconnect structure 206B may further include pads 230, such as contact pads, under bump metallizations (UBMs), or the like to which external connections are made. The pads 230 may comprise aluminum, copper, or the like, and the pads 230 may extend through one or more passivation films 228. Solder regions 232 is disposed on the pads 230. The solder regions 232 may be physically and electrically coupled to the metallization layers of the backside interconnect structure 206B, allowing for electrical connection to other package components.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Thus, a semiconductor device is formed which includes a carrier substrate 100 that is bonded to an integrated circuit die 200 by direct, insulator-to-insulator bonding. In various embodiments, a composite bonding layer 106 is provided on the carrier substrate 100, and the composite bonding layer 106 includes a relatively hard stress buffer layer 102 and a softer, planarization layer 104. The stress buffer layer 102 can be a monolithic layer, or the stress buffer layer 102 can be a multi-layer with a relatively hard base layer 102A and an interfacial layer 102B disposed between the base layer 102A and the planarization layer 104 for improved adhesion. The stress buffer layer 102 provides stress absorption during the bonding process while the planarization layer 104 provides a material that can be easily planarized. Although the figures illustrate a carrier substrate 100 being bonded to the integrated circuit die 200, it should be recognized that the composite bonding layer 106 may also be used to bond other components, such as a heat dissipation feature (e.g., a metal lid), to the integrated circuit die 200 or the carrier substrate 100.

FIGS. 1A through 6B illustrates embodiments where a composite bonding layer is used to bond a carrier substrate to an integrated circuit die with insulator-to-insulator bonding with no electrical connection being made across the composite bonding layer. For example, the composite bonding layer may be free of any conductive features disposed therein. In other embodiments, conductive vias may be formed through the composite bonding layer to allow for the composite bonding layer to be used in bonding processes where electrical connections are made.

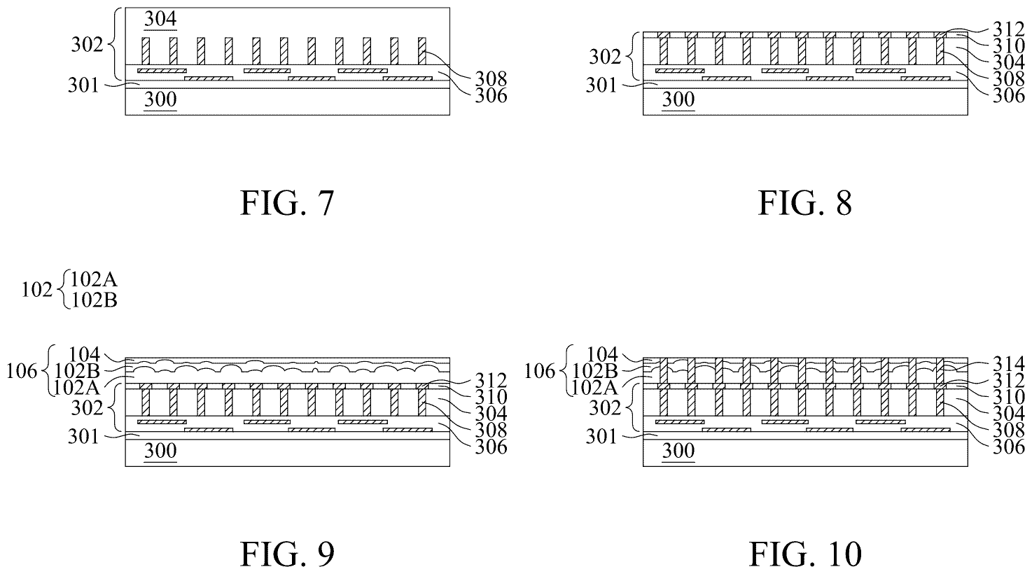

FIGS. 7 through 12 illustrate intermediate stages of manufacturing a semiconductor device (e.g., a semiconductor package) by bonding two or more semiconductor components together with a composite, insulating bonding layer. In FIGS. 7 through 12, like reference numerals indicate like elements formed by like processes as the embodiments of FIGS. 1 through 6B unless otherwise noted.

In FIG. 7, an integrated circuit die 302 is attached to a top surface of a carrier substrate 300. The integrated circuit die 302 includes a semiconductor substrate 304 having active devices disposed thereon, an interconnect structure 306 on a front-side of the semiconductor substrate 304, and conductive vias 308 disposed within the semiconductor substrate 304. The semiconductor substrate 304 and the interconnect structure 306 may be substantially similar to the semiconductor substrate 202 and the front-side interconnect structure 206F, described above. For example, active devices (e.g., transistors) may be disposed on an active surface of the semiconductor substrate 304, and the interconnect structure 306 may include metallization patterns that electrically connect the active devices together to form functional circuits.

The conductive vias 308 are embedded in the substrate 304 and/or the interconnect structure 306. The conductive vias 308 are electrically coupled to metallization patterns of the interconnect structure 306. The conductive vias 308 are also sometimes referred to as TSVs. As an example to form the conductive vias 308, recesses can be formed in the interconnect structure 306 and/or the substrate 304 by, for example, etching, milling, laser techniques, a combination thereof, and/or the like. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, a combination thereof, and/or the like. The barrier layer may be formed from an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from a surface of the interconnect structure 306 or the substrate 304 by, for example, a CMP. Remaining portions of the barrier layer and conductive material form the conductive vias 308. The conductive vias 308 are electrically connected to the metallization patterns of the interconnect structure 306.

The carrier substrate 300 may be substantially similar to the carrier substrate 100, described above. The integrated circuit die 302 may be attached to the carrier substrate using any suitable process. For example, the integrated circuit die may be bonded to the carrier substrate 300 by an insulator-to-insulator bonding process using an insulating bonding layer 301 similar to the manner that the carrier substrate 100 is bonded to the integrated circuit die 200, described above.

In FIG. 8, a planarization process may be performed to planarize a backside of the integrated circuit die 302. The planarization process may be a CMP, an etch-back, combinations thereof, or the like. The planarization may remove portions of the semiconductor substrate 304 to expose the conductive vias 308. Further, bond pads 312 are formed in an insulating bonding layer 310 on the backside of the semiconductor substrate 304. The bond pads 312 may be conductive pads, or the like, to which external connections are made. The bond pads 312 can be formed of a metal, such as copper, aluminum, or the like. In some embodiments, the bond pads 312 may be electrically connected to metallization patterns of the interconnect structure 306 by the conductive vias 308. The bond pads 312 may be disposed in an insulating bonding layer 310 at the backside of the integrated circuit die 302. The insulating bonding layer 310 may be deposited on the semiconductor substrate 304, for example, by PVD, lamination, CVD, or the like. The bond pads 312 may be formed in the insulating bonding layer 310 with a damascene process for example, and a planarization process (e.g., a chemical mechanical polish (CMP) or the like) may be performed such that top surfaces of the bond pads 312 and the insulating bonding layer 310 are coplanar (within process variations).

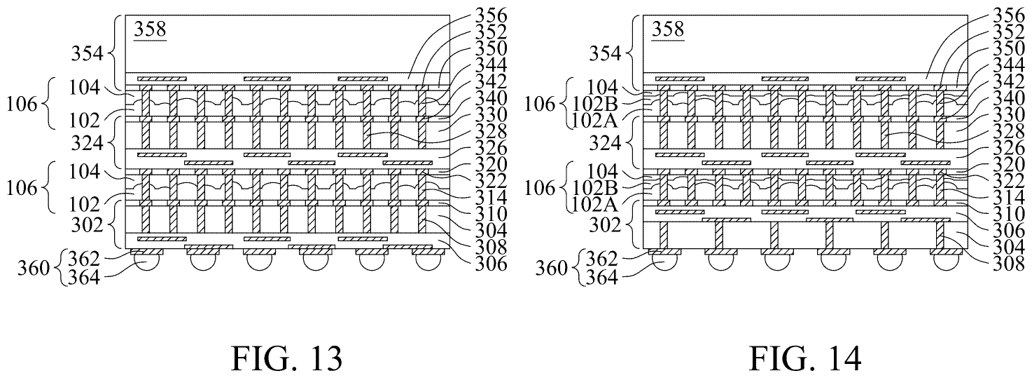

In FIG. 9, the composite bonding layer 106 is formed over the insulating bonding layer 310 and the bond pads 312. The composite bonding layer 106 includes a planarization layer 104 of a relatively soft material and a stress buffer layer 102 (including layers 102A and 102B) of relatively hard material(s). The composite bonding layer 106 may be made of the materials and using the processes described above in FIGS. 1A through 3B. The stress buffer layer 102 may have a multi-layer structure with a base layer 102A and an interfacial layer 102B as illustrated. Alternatively, the interfacial layer 102B may be omitted, and the stress buffer layer 102 may have a monolithic structure (see e.g., FIG. 13). As described above, the stress buffer layer 102 may provide stress relief in the compositing bonding layer 106. Further, a planarization process (e.g., a CMP) may be performed on the top surface of the planarization layer 104 to form the composite bonding layer 106, and the relative softness of the planarization layer 104 allows for a high degree of planarity to be achieved as a result of the planarization process.

In FIG. 10, conductive vias 314 may be formed extending through the composite bonding layer 106 to electrically connect to the bond pads 312. The conductive vias 314 may be made of a metal, such as copper, aluminum, or the like. In some embodiments, the conductive vias 314 may be electrically connected to metallization patterns of the interconnect structure 306 by the conductive vias 308 and the bond pads 312. The bond pads may provide a suitably large landing area on which the conductive vias 314 are formed. The conductive vias 314 may be formed in the composite bonding layer 106 with a damascene process for example, and a planarization process (e.g., a chemical mechanical polish (CMP) or the like) may be performed such that top surfaces of the conductive vias 314 and the composite bonding layer 106 are coplanar (within process variations).

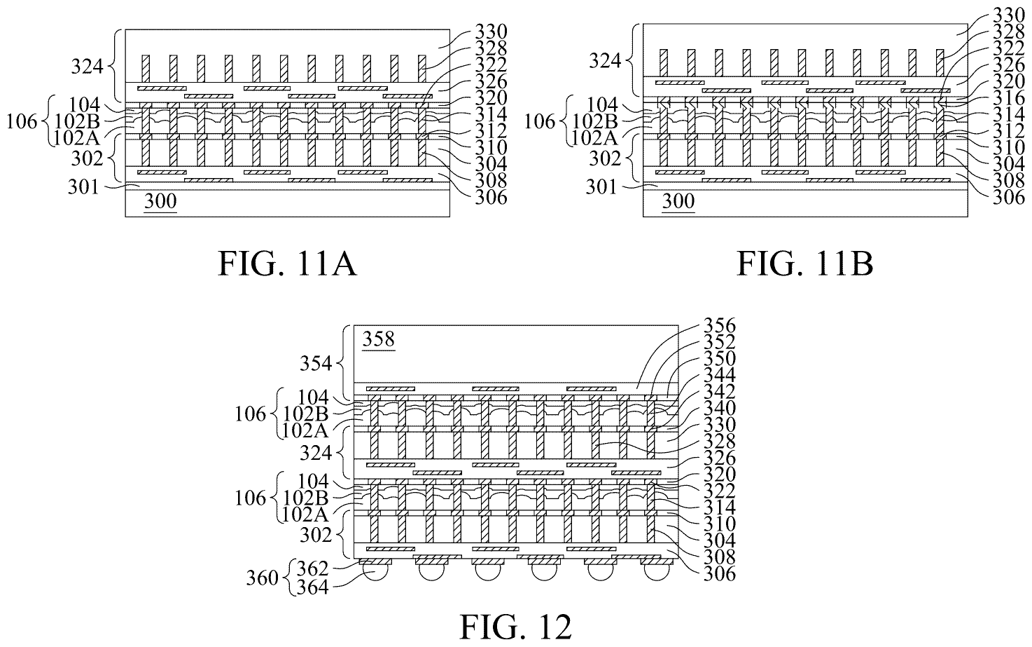

In FIG. 11A, another semiconductor component (an integrated circuit die 324) is bonded to the first semiconductor component (the integrated circuit die 302). The integrated circuit die 324 includes a semiconductor substrate 330 having active devices disposed thereon, an interconnect structure 326 on a front-side of the semiconductor substrate 330, and conductive vias 328 disposed within the semiconductor substrate 330. The semiconductor substrate 330, the interconnect structure 326, and the conductive vias 328 may be substantially similar to the semiconductor substrate 202, the front-side interconnect structure 206F, and the conductive vias 308 respectively described above. For example, active devices (e.g., transistors) may be disposed on an active surface of the semiconductor substrate 330, and the interconnect structure 326 may include metallization patterns that electrically connect the active devices together to form functional circuits, and the conductive vias 328 are electrically connected to the metallization patterns and the active devices. An insulating bonding layer 320 and bond pads 322 are disposed on a front-side of the integrated circuit die 324, such as on a surface of the interconnect structure 326. The insulating bonding layer 320 and the bond pads 322 may be substantially similar to the insulating bonding layer 310 and the bond pads 312 respectively described above. FIG. 11A illustrates an embodiment were the bond pads 322 are directly bonded to the conductive vias 328 with a metal-to-metal bonding process. In other embodiments, a bond pad (e.g., bond pads 316, see FIG. 11B) may be formed on each of the conductive vias 328, and the bond pads 322 are bonded to the conductive vias 328 through these bond pads (e.g., bond pads 316).

The integrated circuit die 324 and the integrated circuit die 302 are directly bonded in a face-to-back manner by an insulator-to-insulator bonding and metal-to-metal bonding process (sometimes referred to as hybrid bonding), such that the front-side of the integrated circuit die 324 is bonded to the backside side of the integrated circuit die 302. Specifically, the insulating bonding layer 320 of the integrated circuit die 324 is bonded to the composite, bonding layer 106 on the integrated circuit die 302 through insulator-to-insulator bonding, without using any adhesive material (e.g., die attach film), and the bond pads 322 of the integrated circuit die 324 is bonded to the conductive vias 314 on the integrated circuit die 302 through metal-to-metal bonding, without using any eutectic material (e.g., solder). The bonding may include a surface activation, a pre-bonding, and an annealing. The surface activation may include activating the insulating bonding layer 320 and/or the composite bonding layer 106 (e.g., the planarization layer 104 of the composite bonding layer 106) may be performed using, e.g., a dry treatment, a wet treatment, a plasma treatment, exposure to H2, exposure to N2, exposure to O2, combinations of these, or the like. In embodiments where a wet treatment is used, an RCA cleaning process may be used, for example. Through the activation treatment, the number of OH groups at surface(s) of the insulating bonding layer 320 and/or the composite bonding layer 106 increases. After surfaces of the insulating bonding layer 320 and/or the composite bonding layer 106 increases are activated, a pre-bonding is performed by applying a small pressing force to press the integrated circuit die 324 against the integrated circuit die 302. The pre-bonding is performed at a low temperature, such as room temperature, such as a temperature in the range of about 15° C. to about 30° C. The bonding strength of the bonding layers 320 and 106 is then improved in a subsequent annealing step, in which the insulating bonding layers 320 and 106 are annealed at a high temperature, such as a temperature in the range of about 100° C. to about 450° C. After the annealing, bonds, such as covalent bonds, are formed bonding the insulating bonding layers 320 and 106. The bond pads 322 and the conductive vias 314 are connected to each other with a one-to-one correspondence. The bond pads 322 and the conductive vias 314 may be in physical contact after the pre-bonding, or may expand to be brought into physical contact during the annealing. Further, during the annealing, the material of the bond pads 322 and the conductive vias 314 (e.g., copper) intermingles, so that metal-to-metal bonds are also formed. Hence, the resulting bonds are hybrid bonds that include both insulator-to-insulator bonds and metal-to-metal bonds. After bonding, the circuitry within the integrated circuit die 324 may be electrically connected to the circuity of the integrated circuit die 302 by the bond pads 322, the conductive vias 314, the bond pads 312, and the conductive vias 308.

The steps described above in FIGS. 7 through 11B may be repeated any number of times until a desired number of semiconductor components (e.g., integrated circuit dies) are bonded together. For example, FIGS. 12 illustrates further processing where a third integrated circuit die 354 is bonded to the integrated circuit dies 302 and 324. To achieve the structure of FIG. 12, a planarization process may be performed on a backside of the semiconductor substrate 330 to expose the conductive vias 328 using a similar process as described above in FIG. 8. Then, an insulating bonding layer 340 and bond pads 342 are formed over the backside of the semiconductor substrate 330 using a similar process as described above in FIG. 8, and another composite bonding layer 106 is formed over the insulating bonding layer 340 as described above in FIG. 9. Conductive vias 344 are then formed extending through the composite bonding layer 106 using a similar process as described above in FIG. 10.

Then, the integrated circuit die 354 is bonded to the backside of the integrated circuit die 324 using a similar process as described above in FIGS. 11A/11B. The integrated circuit die 354 includes a semiconductor substrate 358 having active devices disposed thereon and an interconnect structure 356 on a front-side of the semiconductor substrate 358. The semiconductor substrate 358 and the interconnect structure 356 may be substantially similar to the semiconductor substrate 202 and the front-side interconnect structure 206F respectively described above. For example, active devices (e.g., transistors) may be disposed on an active surface of the semiconductor substrate 358, and the interconnect structure 356 may include metallization patterns that electrically connect the active devices together to form functional circuits. An insulating bonding layer 350 and bond pads 352 are disposed on a front-side of the integrated circuit die 354, such as on a surface of the interconnect structure 356. The insulating bonding layer 350 and the bond pads 352 may be substantially similar to the insulating bonding layer 310 and the bond pads 312 respectively described above. The integrated circuit die 354 may be bonded to the backside of the integrated circuit die 324 using a similar process as described above in FIGS. 11A/11B. For example, the bonding process may be a combination of insulator-to-insulator bonding between the composite bonding layer 106 and the insulating bonding layer 350 as well as by metal-to-metal bonding between the bond pads 352 and the conductive vias 344.

After a desired number of semiconductor components are bonded together, the carrier substrate 300 may be removed. Removing the carrier substrate may be achieved by a planarization process (e.g., CMP), for example. Then, external connectors can be made on the front side of the integrated circuit die 302, which allow the stacked integrated circuit dies to be bonded to another package component. The external connectors 360 may include UBMs 362 and solder regions 364. In some embodiments, the external connectors 360 may be microbumps, C4 bumps, or the like.

Thus, as described above in FIGS. 7 through 12, embodiment composite bonding layers may include conductive vias formed therein that allow for electrical connection to be made between bonded semiconductor components. Other configurations are also possible. For example, FIG. 12 illustrates the composite bonding layers 106 with the optional interfacial layer 102B. In other embodiments, as illustrated by FIG. 13, the interfacial layer 102B may be omitted from one or more of the composite bonding layers 106. The structure of FIG. 13 may be substantially similar to the structure of FIG. 12 where like reference numerals indicate like elements formed by like processes. However, in FIG. 13, the dielectric stress buffer layer 102 of the composite bonding layers 106 have a monolithic composition, and the interfacial layer 102B is excluded.

Further, although FIGS. 7-12 describe embodiments where integrated circuit dies are bonded together in a face-to-back bonding process, other embodiments may include face-to-face bonding processes as illustrated by FIG. 14. The structure of FIG. 14 may be substantially similar to the structure of FIG. 12 where like reference numerals indicate like elements formed by like processes. However, in FIG. 14, the integrated circuit die 324 is bonded to the integrated circuit die 302 in a face-to-face configuration where a front-side of the integrated circuit die 324 is bonded to a front-side of the integrated die 302 such that the interconnect structures 306 and 326 face each other. Although FIG. 14 illustrates the composite bonding layers 106 as including the interfacial layers 102B, it should be understood that the interfacial layers 102B are optional and can be omitted in other embodiments.

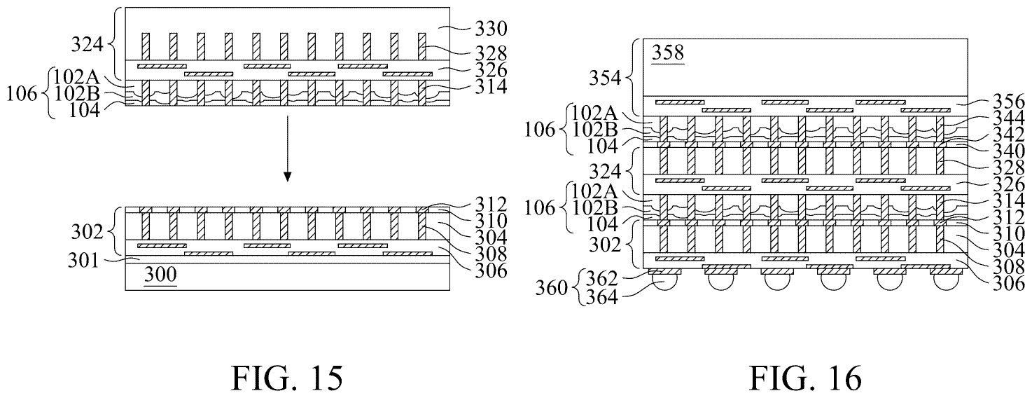

FIGS. 7 through 12 illustrate embodiments where the composite bonding layer 106 is deposited on a backside of the integrated circuit die 302 and then then integrated circuit die 324 is bonded to the composite bonding layer 106. In other embodiments, the composite bonding layer 106 may be formed on a front-side of the integrated circuit die 324 prior to bonding the integrated circuit dies 302 and 324 together. FIGS. 15 through 18 illustrate such embodiments. In FIGS. 15 through 18, like reference numerals indicate like elements formed by like processes as FIGS. 7 through 12 unless otherwise noted.

Referring to FIG. 15, the integrated circuit die 302 is attached to the carrier substrate 300, and the insulating bonding layer 310 and bond pads 312 are formed on a backside of the integrated circuit die 302. Further, the composite bonding layer 106 is formed over the front-side of the integrated circuit die 324, such as on the interconnect structure 326. The bonding layer 106 may include a relatively hard, stress buffer layer 102 (including a dielectric base layer 102A and an optional interfacial layer 102B) and a relatively soft planarization layer 104 as described above in FIGS. 1A through 2B. The composite bonding layer 106 may be formed by sequentially depositing the stress buffer layer 102 and the planarization layer 104 over a top surface of the interconnect structure 326 and then planarizing an exposed surface of the planarization layer 104 as described above in FIGS. 3A and 3B. The relative softness of the planarization layer 104 provides a material that is conducive to planarization while the relative hardness of the stress buffer layer 102 provides stress absorption in the bonded device. Conductive vias 314 may be formed through the composite bonding layer 106 in a similar manner as described above in FIG. 10. The conductive vias 314 may be electrically connected to metallization patterns in the interconnect structure 326. The integrated circuit die 324 may then be aligned face-down towards the integrated circuit die 302.

Subsequently, the integrated circuit dies 324 and 302 may be directly bonded together with insulator-to-insulator and metal-to-metal bonding in a similar manner as described above in FIGS. 11A/11B. For example, the conductive vias 314 may be directly bonded to the bond pads 312 with metal-to-metal bonds without solder, and the composite bonding layer 106 (e.g., the planarization layer 104) may be directly contacted to and bonded with the bonding layer 312. The bonding process may be repeated any number of times until a desired number of integrated circuit dies are bonded together, the carrier substrate 300 may then be removed, and external connectors 360 may be formed on the integrated circuit die 302. The resulting package is illustrated in FIG. 16.

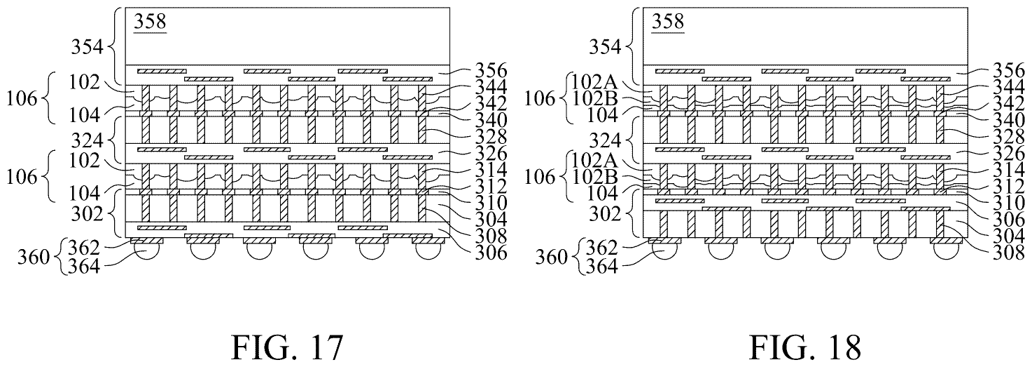

The process described in FIGS. 15 and 16 may be applied to other package configurations as well. Other configurations are also possible. For example, FIG. 16 illustrates the composite bonding layers 106 with the optional interfacial layer 102B. In other embodiments, as illustrated by FIG. 17, the interfacial layer 102B may be omitted from one or more of the composite bonding layers 106. The structure of FIG. 17 may be substantially similar to the structure of FIG. 16 where like reference numerals indicate like elements formed by like processes. However, in FIG. 17, the dielectric stress buffer layer 102 of the composite bonding layers 106 have a monolithic composition, and the interfacial layer 102B is excluded.

Further, although FIGS. 15 through 16 describe embodiments where integrated circuit dies are bonded together in a face-to-back bonding process, other embodiments may include face-to-face bonding processes as illustrated by FIG. 18. The structure of FIG. 18 may be substantially similar to the structure of FIG. 16 where like reference numerals indicate like elements formed by like processes. However, in FIG. 18, the integrated circuit die 324 is bonded to the integrated circuit die 302 in a face-to-face configuration where a front-side of the integrated circuit die 324 is bonded to a front-side of the integrated die 302 such that the interconnect structures 306 and 326 face each other. Although FIG. 18 illustrates the composite bonding layers 106 as including the interfacial layers 102B, it should be understood that the interfacial layers 102B are optional and can be omitted in other embodiments.

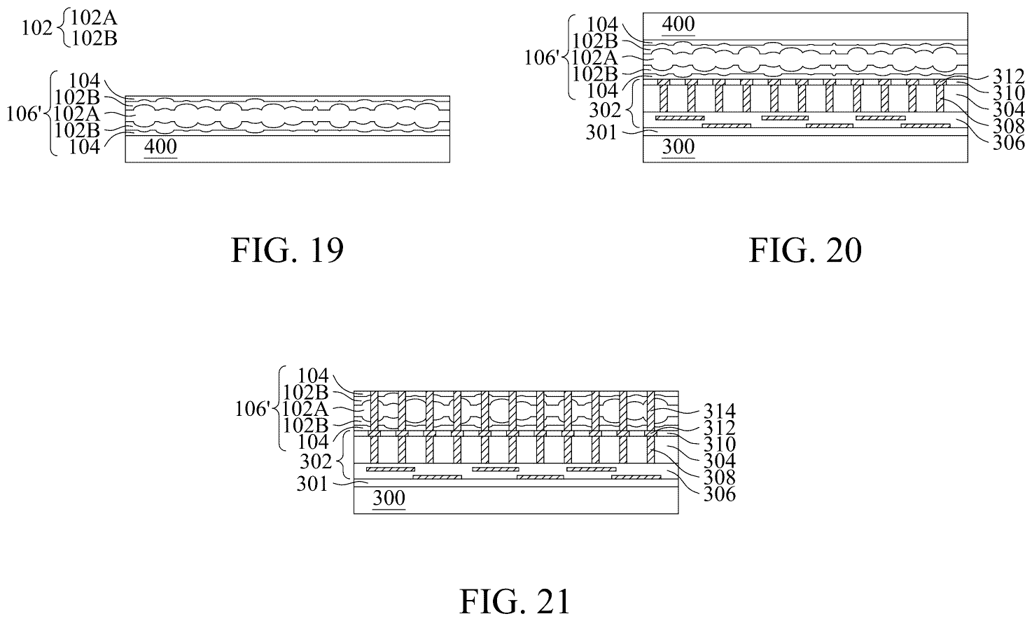

In other embodiments, the composite bonding layer 106 may be formed on a sacrificial, carrier substrate, and integrated circuit dies maybe sequentially bonded to opposing surfaces of the composite bonding layer 106. FIGS. 19 through 25 illustrate such embodiments. In FIGS. 19 through 25, like reference numerals indicate like elements formed by like processes as FIGS. 7 through 12 unless otherwise noted.

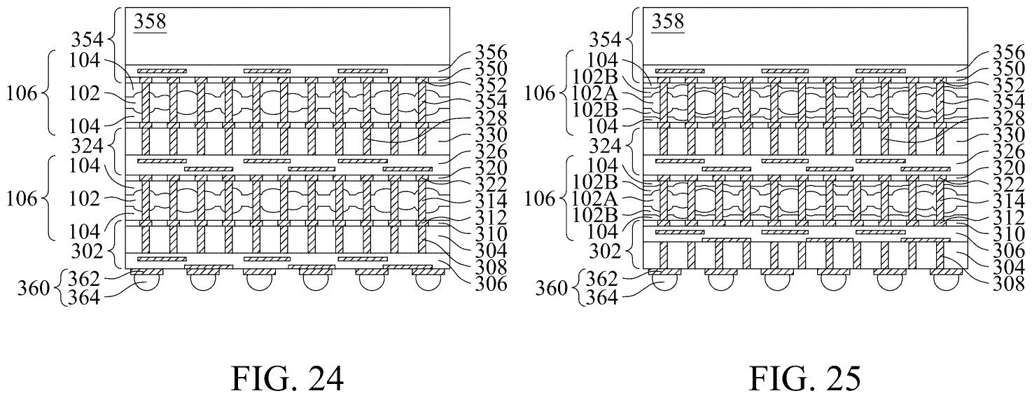

Referring to FIG. 19, a composite bonding layer 106′ is formed on a carrier substrate 400. The carrier substrate 400 may be substantially similar to the carrier substrate 100 described above. The composite bonding layer 106′ may be substantially similar to the composite bonding layer 106 described above in FIGS. 1A through 3B. However, the composite bonding layer 106′ includes a dielectric stress buffer layer 102 that is sandwiched between two planarization layers 104. In some embodiments, the dielectric stress buffer layer 102 may include a dielectric base layer 102A between two, optional interfacial layers 102B. The interfacial layers 102B are disposed between the base layer 102A and respective ones of the planarization layers 104 for improved adhesion. In other embodiments, the interfacial layers 102B are omitted, and the dielectric stress buffer layer 102 has a monolithic structure (see e.g., FIG. 24).

Each layer of the composite bonding layer 106′ may be made of the materials and deposited using the methods described above. For example, forming the composite bonding layer 106′ may include sequentially depositing a bottom planarization layer 104 over the substrate; depositing the dielectric stress buffer layer 102 over the bottom planarization layer 104; and depositing a top planarization layer 104 over the dielectric stress buffer layer 102. Then, a planarization process (e.g., a CMP) is applied to a top surface of the top planarization layer 104, and the relatively soft material of the second planarization layer 104 allows for a high degree of planarity to be achieved. The bottom planarization layer 104 is included in the composite bonding layer 106′ because a bottom surface of the composite bonding layer 106′ facing the support substrate 400 will also be planarized subsequently.

In FIG. 20, the carrier substrate 400 is bonded to the integrated circuit die 302. The integrated circuit die 302 may be processed to a similar stage as described above in FIG. 8. For example, the integrated circuit die 302 may include a semiconductor substrate 304, conductive vias 308 in the semiconductor substrate, and an interconnect structure 306. The integrated circuit die 302 is bonded to a support substrate 300, and a bonding layer 310 and bond pads 312 are formed on a backside of the integrated circuit die 302. In some embodiments, the composite bonding layer 106′ may be directly bonded to an insulating bonding layer 310 with an insulator-to-insulator bonding process as described above. For example, the top planarization layer of the composite bonding layer 106 may be directly bonded to the insulating bonding layer 310.

In FIG. 21, a planarization process (e.g., a CMP) may be performed to remove the substrate 400 and expose the composite bonding layer 106′. For example, the planarization process may be applied to a top surface of the bottom planarization layer 104 (the surface facing the substrate 400). The relatively soft material of the first planarization layer 104 allows for a high degree of planarity to be achieved. After the carrier substrate 400 is removed, conductive vias 314 are formed through the composite bonding layer 106′ to contact the bond pads 312 using a similar process as described above in FIG. 10.

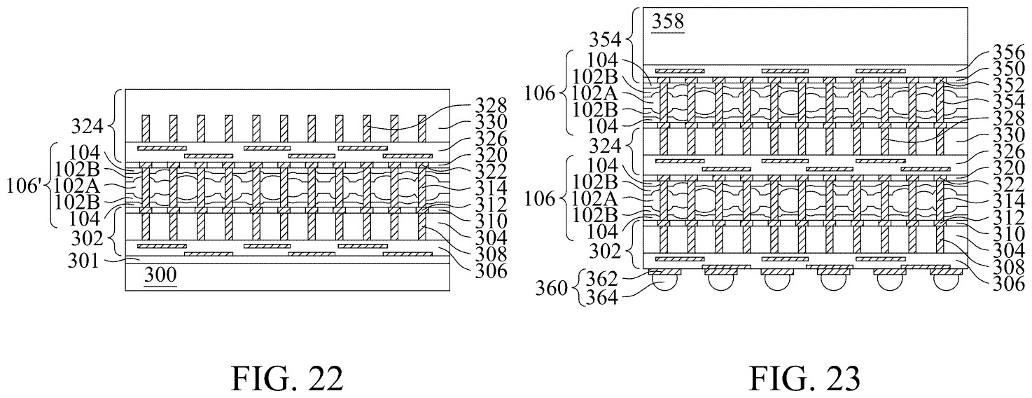

In FIG. 22, another integrated circuit die 324 is directly bonded to integrated circuit die 302. The integrated circuit dies 324 and 302 may be bonded together with insulator-to-insulator and metal-to-metal bonding in a similar manner as described above in FIGS. 11A/11B. For example, the conductive vias 314 may be directly bonded to the bond pads 322 of the integrated circuit die 324 with metal-to-metal bonds without solder, and the composite bonding layer 106′ (e.g., the bottom planarization layer 104) may be directly contacted to and bonded with the insulating bonding layer 320 of the integrated circuit die 324. The bonding process of FIGS. 19 through 22 may be repeated any number of times until a desired number of integrated circuit dies are bonded together, the carrier substrate 300 may then be removed, and external connectors 360 may be formed on the integrated circuit die 302 in a similar manner as described above in FIG. 12. The resulting package is illustrated in FIG. 23.

The process described in FIGS. 19 through 23 may be applied to other package configurations as well. For example, FIG. 23 illustrates the composite bonding layers 106′ with the optional interfacial layers 102B. In other embodiments, as illustrated by FIG. 24, the interfacial layers 102B may be omitted from one or more of the composite bonding layers 106′. The structure of FIG. 24 may be substantially similar to the structure of FIG. 23 where like reference numerals indicate like elements formed by like processes. However, in FIG. 24, the dielectric stress buffer layer 102 of the composite bonding layers 106′ have a monolithic composition, and the interfacial layers 102B are excluded.

Further, although FIGS. 19 through 23 describe embodiments where integrated circuit dies are bonded together in a face-to-back bonding process, other embodiments may include face-to-face bonding processes as illustrated by FIG. 25. The structure of FIG. 25 may be substantially similar to the structure of FIG. 23 where like reference numerals indicate like elements formed by like processes. However, in FIG. 25, the integrated circuit die 324 is bonded to the integrated circuit die 302 in a face-to-face configuration where a front-side of the integrated circuit die 324 is bonded to a front-side of the integrated die 302 such that the interconnect structures 306 and 326 face each other. Although FIG. 25 illustrates the composite bonding layers 106′ as including the interfacial layers 102B, it should be understood that the interfacial layers 102B are optional and can be omitted in other embodiments.

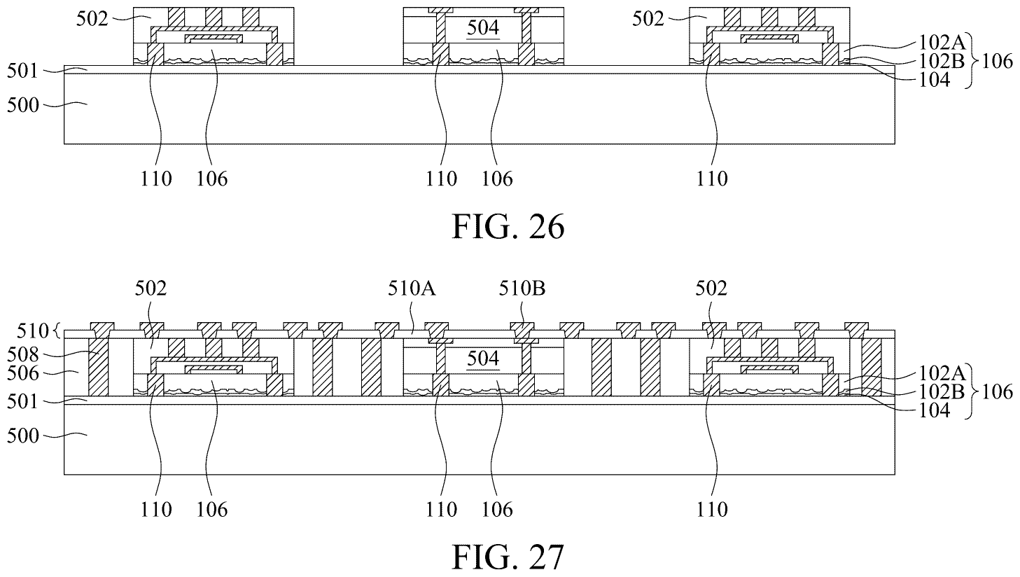

Embodiment compositing bonding layers may also be applied to the packaging of passive components, such as passive device dies (e.g., integrated passive devices (IPDs)), local silicon interconnect (LSI) dies, or the like. For example, FIGS. 26 through 30 illustrate cross-sectional views of various intermediate stages of forming a package structure where passive components are bonded to a carrier substrate. In FIGS. 26 through 30, like reference numerals indicate like elements formed by like processes as FIGS. 1A through 3B unless otherwise noted.

In FIG. 26, passive components 502 and 504 are bonded to a carrier substrate 500. The carrier substrate 500 may be substantially similar to the carrier substrate 100 described above. An insulating bonding layer 501 is deposited on a top surface of the carrier substrate 500. The insulating bonding layer 501 may be substantially similar to the insulating bonding layer 301 described above.

The passive components include LSI dies 502 and a passive device dies 504. The LSI dies 502 may include conductive metallizations that formed in and/or on a substrate (e.g., a semiconductor substrate, such as a silicon substrate) that will electrically connect subsequently bonded integrated circuit dies together. For example, the LSI dies 502 may bridges a subsequently bonded logic die to subsequently bonded memory dies, and translates command between the logic die and the memory dies. The passive device dies 504 may include an IPD, surface mount devices (SMDs), or the like that provide discrete functionality of a passive component (e.g., a capacitor, resistor, inductor, or the like) in the package. Other combinations of passive components may be attached to the carrier substrate 500 in other embodiments.

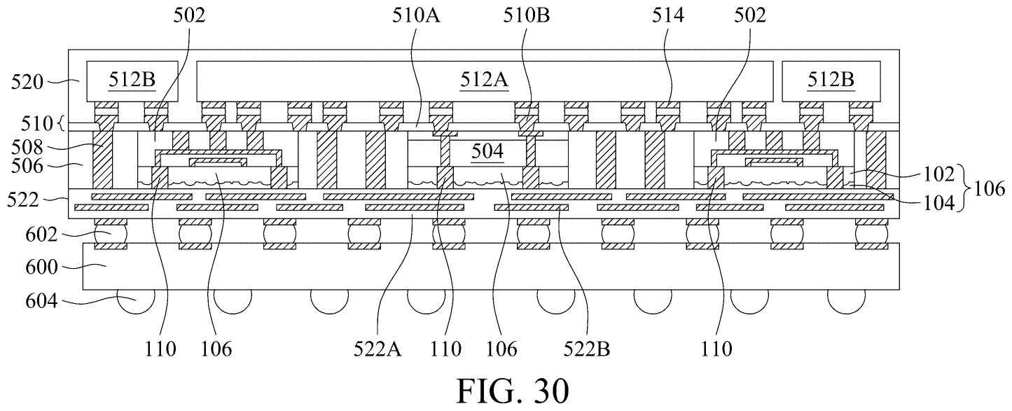

In various embodiments, composite bonding layers 106 may be formed on the LSI dies 502 and the passive device die 504. The composite bonding layer 106 includes a planarization layer 104 of a relatively soft material and a stress buffer layer 102 (including layers 102A and 102B) of relatively hard material(s). The composite bonding layer 106 may be made of the materials and using the processes described above in FIGS. 1A through 3B. The stress buffer layer 102 may have a multi-layer structure with a base layer 102A and an interfacial layer 102B as illustrated. Alternatively, the interfacial layer 102B may be omitted, and the stress buffer layer 102 may have a monolithic structure (see e.g., FIG. 30). As described above, the stress buffer layer 102 may provide stress relief in the compositing bonding layer 106. Further, a planarization process (e.g., a CMP) may be performed on the surface of the planarization layer 104 that faces away from the LSI dies 502 or passive device die 504 as part of forming the composite bonding layer 106. The relative softness of the planarization layer 104 allows for a high degree of planarity to be achieved as a result of the planarization process. Conductive vias 110 are formed extending through the composite bonding layers to electrically connect to metallization layers in the LSI dies 502 or passive device die 504. The conductive vias 110 may be formed of similar materials and using a similar process as the conductive vias 314 described above.

The passive components (e.g., the LSI dies 502 and the passive device die 504) are directly bonded to the package substrate 500 by an insulator-to-insulator bonding between the composite bonding layers 106 and the insulating bonding layers 501. The insulator-to-insulator bonding process may be substantially similar as that described above with respect to FIGS. 5A and 5B.

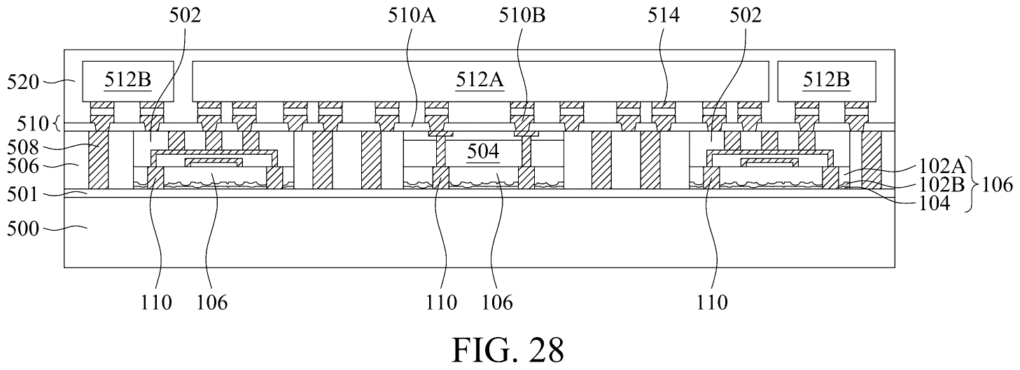

In FIG. 28, an encapsulant 506 is formed on and around the various passive components. After formation, the encapsulant 506 encapsulates LSI dies 502 and the passive device die 504. The encapsulant 506 may be a molding compound, epoxy, or the like. The encapsulant 506 may be applied by compression molding, transfer molding, or the like. The encapsulant 506 may be applied in liquid or semi-liquid form and then subsequently cured. A planarization process may then be applied to level top surfaces of the encapsulant 506, the LSI dies 502, and the passive device die 504. Conductive vias 508 are also formed in the encapsulant 506 using a suitable process, such as a process similar to forming the conductive vias 314 described above. Alternatively, the conductive vias 508 could be plated on the carrier substrate 500 prior to depositing the encapsulant 506.

As also illustrated in FIG. 28, a redistribution structure 510 is formed over the conductive vias 508, the LSI dies 502, and the passive device die 504. The redistribution structure 510 includes metallization patterns 510B that is disposed in a dielectric layer 510A. The metallization patterns 510B may be electrically connected to the conductive vias 508, the LSI dies 502, and the passive device die 504.

In some embodiments, the dielectric layer 510A is formed of a polymer, which may be a photosensitive material such as PBO, polyimide, a BCB-based polymer, or the like, that may be patterned using a lithography mask. In other embodiments, the dielectric layer 510A is formed of a nitride such as silicon nitride; an oxide such as silicon oxide, PSG, BSG, BPSG; or the like. The dielectric layer 510A may be formed by spin coating, lamination, CVD, the like, or a combination thereof. The dielectric layer 510A is then patterned to expose underlying conductive features, such as portions of the underlying conductive vias 508, the LSI dies 502, and the passive device dies 504. The patterning may be by an acceptable process, such as by exposing the dielectrics layer to light when the dielectric layer 510A is a photosensitive material, or by etching using, for example, an anisotropic etch. If the dielectric layer 510A is a photosensitive material, the dielectric layer 510A can be developed after the exposure.

The metallization pattern 510B can include UBMs. As an example to form a metallization pattern 510B, a seed layer (not illustrated) is formed over the respective underlying features. For example, the seed layer can be formed on a dielectric layer 510A and in the openings through the respective dielectric layer 510A. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization pattern 510B. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may comprise a metal or a metal alloy, such as copper, titanium, tungsten, aluminum, the like, or combinations thereof. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the metallization pattern 510B.

In FIG. 28, integrated circuit dies 512 (labeled 512A and 512B) are bonded to redistribution structure 510. The integrated circuit dies 512 may be bonded to the redistribution structure 510 with solder bonds, such as with conductive connectors 514. Multiple integrated circuit dies 512 are placed adjacent one another in. The integrated circuit dies 512 may include a logic device 512A and memory devices 512B. The logic dies 512A and the memory dies 512B may be formed in processes of a same technology node, or may be formed in processes of different technology nodes. For example, the logic dies 512A may be formed by a more advanced process node than the memory dies 512B.

Each logic die 512A may be a central processing unit (CPU), graphics processing unit (GPU), system-on-a-chip (SoC), microcontroller, or the like. The logic dies 512A may be integrated circuit dies (similar to the integrated circuit die 302 described for FIG. 7) or may be die stacks. In some embodiments, the logic dies 512A are integrated circuit dies such as system-on-a-chip (SoC) dies. In some embodiments, the logic dies 512A are die stacks such as system-on-integrated-chip (SoIC) devices.

Each memory die 512B may be a dynamic random access memory (DRAM) die, static random access memory (SRAM) die, hybrid memory cube (HMC) module, a high bandwidth memory (HBM) module, or the like. The memory dies 512B may be integrated circuit dies (similar to the integrated circuit die 302 described for FIG. 7) or may be die stacks. In some embodiments, the memory dies 512B are die stacks, such as high bandwidth memory (HBM) devices. The LSI dies 502 electrically connect and provide signal lines between the logic dies 512A and each of the memory dies 512B.

After the integrated circuit dies 512 are bonded to the redistribution structure 510, an encapsulant 520 may be formed around the integrated circuit dies 512. The encapsulant 520 may be made of a similar material using similar processes as the encapsulant 506 described above in FIG. 27.

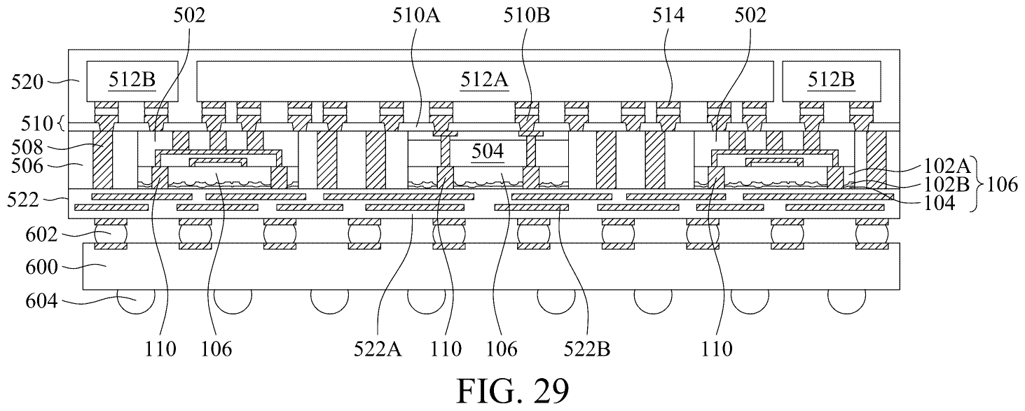

In FIG. 29, the carrier substrate 500 and optionally the insulating bonding layer 501 is removed by a planarization process, for example. The planarization process may be applied until the conductive vias 110 in the composite bonding layers 106 and the conductive vias 508 in the encapsulant 506 are exposed. Then, a redistribution structure 522 is formed on an opposing side of the passive components as the redistribution structure 510. The redistribution structure 510 may be made of similar materials using similar processes the redistribution structure 522 described above. The redistribution structure 522 includes metallization patterns 522B formed in one or more dielectric layers 522A. The conductive vias 508 provide electrical connection between the redistribution structures 510 and 522. Further, the redistribution structure 522 may be electrically connected to the LSI dies 502 and the passive device dies 504 by the conductive vias 110. After the redistribution structure 522 is formed, it may be bonded to another package component, such as a package substrate 600. The package substrate 600 may be bonded to the redistribution structure 522 with solder bonds, such as with conductive connectors 602. The package substrate 600 may include additional solder connectors 604, which allows the package substrate 600 to be bonded to yet another package component.

The process described in FIGS. 26 through 29 may be applied to other package configurations as well. For example, FIG. 29 illustrates the composite bonding layers 106 with the optional interfacial layers 102B. In other embodiments, as illustrated by FIG. 30, the interfacial layers 102B may be omitted from one or more of the composite bonding layers 106. The structure of FIG. 30 may be substantially similar to the structure of FIG. 29 where like reference numerals indicate like elements formed by like processes. However, in FIG. 30, the dielectric stress buffer layer 102 of the composite bonding layers 106 have a monolithic composition, and the interfacial layers 102B are excluded.

Various embodiments provide a composite, insulating bonding layer for bonding two semiconductor components together. In some embodiments, the semiconductor components include a semiconductor die that is directly bonded to a support substrate or a heat dissipation feature with the composite bonding layer in an insulator-to-insulator bonding process. In some embodiments, the semiconductor components include two semiconductor dies that are directly bonded together with the composite bonding layer in an insulator-to-insulator and metal-to-metal bonding process. In some embodiments, the semiconductor components include a passive device die or a local silicon interconnect LSI die that is attached to a carrier substrate with the composite bonding layer in an insulator-to-insulator bonding process. Other types of package components are also contemplated.

The composite bonding layer includes at least two layers: a stress buffer layer made of a relatively hard material and a planarization layer made of a relatively soft material. The stress buffer layer made of the relatively hard material acts as a stress buffer layer to improve mechanical integrity and reduce manufacturing defects. The planarization layer is made of a relatively soft material, which is more conducive to achieving a high degree of planarity with a planarization process (e.g., CMP). As a result, the composite bonding layer can achieve improved planarity with a softer, planarization layer while still having stress relief in the harder, stress buffer layer.

In some embodiments, a semiconductor device includes a first semiconductor component and a composite bonding layer on the first semiconductor component, the composite bonding layer comprising: a dielectric stress buffer layer; and a dielectric planarization layer, wherein a hardness of the dielectric stress buffer layer is greater than a hardness of the dielectric planarization layer. The semiconductor device further includes a second semiconductor component bonded to the first semiconductor component by insulator-to-insulator bonding between the composite bonding layer and an insulating bonding layer on the second semiconductor component, wherein the dielectric planarization layer is disposed an interface between the composite bonding layer and the insulating bonding layer. Optionally, in some embodiments, a ratio of the hardness of the dielectric stress buffer layer to the hardness of the dielectric planarization layer is in a range of 10:7 to 10:8. Optionally, in some embodiments, the dielectric stress buffer layer is more crystalline than the dielectric planarization layer. Optionally, in some embodiments, the dielectric stress buffer layer is a monolithic layer. Optionally, in some embodiments, the dielectric stress buffer layer comprises: a base layer, and an interfacial layer between the base layer and the dielectric planarization layer, wherein a hardness of the interfacial layer is greater than the hardness of the dielectric planarization layer and less than a hardness of the base layer. Optionally, in some embodiments, the first semiconductor component is an integrated circuit die, and wherein the second semiconductor component is a semiconductor substrate free of any devices. Optionally, in some embodiments, the first semiconductor component is a first integrated circuit die, and wherein the second semiconductor component is a second integrated circuit die. Optionally, in some embodiments, the semiconductor device further includes conductive vias extending through the composite bonding layer; and bonding pads in the insulating bonding layer, wherein the second semiconductor component is bonded to the first semiconductor component by metal-to-metal bonding between the conductive vias and the bonding pads.

In some embodiments, a semiconductor device includes a first integrated circuit die and a composite bonding layer on a surface of the first integrated circuit die. The composite bonding layer comprises: a dielectric stress buffer layer and a first dielectric planarization layer. A hardness of the dielectric stress buffer layer is greater than a hardness of the first dielectric planarization layer, and the dielectric stress buffer layer is disposed between the first dielectric planarization layer and the first integrated circuit die. The semiconductor device further includes conductive vias extending through the composite bonding layer; a second integrated circuit die; an insulating bonding layer on a surface of the second integrated circuit die; and bond pads in the insulating bonding layer. The first integrated circuit die and the second integrated circuit die are bonded together by insulator-to-insulator bonding between the composite bonding layer and the insulating bonding layer; and metal-to-metal bonding between the conductive vias and the bond pads. Optionally, in some embodiments, the composite bonding layer further comprises a second dielectric planarization layer between the dielectric stress buffer layer and the first integrated circuit die. Optionally, in some embodiments, a ratio of the hardness of the dielectric stress buffer layer to the hardness of the first dielectric planarization layer is in a range of 10:7 to 10:8. Optionally, in some embodiments, the first dielectric planarization layer is more amorphous than the dielectric stress buffer layer. Optionally, in some embodiments, the first dielectric planarization layer comprises silicon oxide, silicon carbonitride, silicon oxynitride, or aluminum oxide, and wherein the dielectric stress buffer layer comprises polyimide, silicone, silicon oxide, a nitride, a carbide, or a combination thereof.

In some embodiments, a method includes depositing a composite bonding layer over a first semiconductor component. The composite bonding layer comprises a dielectric stress buffer layer and a first dielectric planarization layer. A hardness of the dielectric stress buffer layer is greater than a hardness of the first dielectric planarization layer. The method further includes performing a planarization process on the first dielectric planarization layer; and bonding a second semiconductor component to the first semiconductor component by directly bonding the composite bonding layer to a first insulating bonding layer on the second semiconductor component with insulator-to-insulator bonding. Optionally, in some embodiments, depositing the composite bonding layer comprises depositing the first dielectric planarization layer at a lower temperature than the dielectric stress buffer layer. Optionally, in some embodiments, the dielectric stress buffer layer is more crystalline than the first dielectric planarization layer. Optionally, in some embodiments, the method further includes forming a plurality of conductive vias extending through the composite bonding layer, wherein bonding the second semiconductor component to the first semiconductor component further comprises directly bonding the conductive vias to bond pads in the first insulating bonding layer with metal-to-metal bonding. Optionally, in some embodiments, the method further includes removing the first semiconductor component to expose a surface of the composite bonding layer opposite to the second semiconductor component; and bonding a third semiconductor component to the surface of the composite bonding layer opposite to the second semiconductor component by directly bonding the composite bonding layer to a second insulating bonding layer on the third semiconductor component with insulator-to-insulator bonding. Optionally, in some embodiments, the composite bonding layer comprises a second dielectric planarization layer, wherein the hardness of the dielectric stress buffer layer is greater than a hardness of the second dielectric planarization layer, and wherein removing the first semiconductor component comprises a planarization process that planarizes the second dielectric planarization layer. Optionally, in some embodiments, the dielectric stress buffer layer comprises: a base layer, and an interfacial layer between the base layer and the first dielectric planarization layer, wherein a hardness of the interfacial layer is greater than the hardness of the first dielectric planarization layer and less than a hardness of the base layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first semiconductor component; and
a composite bonding layer on the first semiconductor component, the composite bonding layer comprising:
a dielectric stress buffer material; and
a dielectric planarization material, wherein the dielectric stress buffer material is disposed between the dielectric planarization material and the first semiconductor component wherein a hardness of the dielectric stress buffer material is greater than a hardness of the dielectric planarization material, and wherein a surface roughness of a surface of the dielectric stress buffer material that is opposite to the first semiconductor component is greater than a surface roughness of a surface of the dielectric planarization material that is opposite to the first semiconductor component.

2. The semiconductor device of claim 1, wherein a ratio of the hardness of the dielectric stress buffer material to the hardness of the dielectric planarization material is in a range of 10:7 to 10:8.

3. The semiconductor device of claim 1, wherein the dielectric stress buffer material is more crystalline than the dielectric planarization material.

4. The semiconductor device of claim 1, wherein the dielectric stress buffer material is a monolithic layer, wherein the dielectric stress buffer layer contacts the first semiconductor component, and wherein the dielectric planarization material contacts the surface of the dielectric stress buffer material that is opposite to the first semiconductor component.

5. The semiconductor device of claim 1, wherein the dielectric stress buffer material comprises:
a base material, and
an interfacial material between the base material and the dielectric planarization material, wherein a hardness of the interfacial material is greater than the hardness of the dielectric planarization material and less than a hardness of the base material.

6. The semiconductor device of claim 1, wherein the first semiconductor component is an integrated circuit die, and wherein integrated circuit die is bonded to a support substrate by the composite bonding layer through dielectric-to-dielectric bonding.

7. The semiconductor device of claim 1, wherein the first semiconductor component is a first integrated circuit die, and wherein integrated circuit die is bonded to a second integrated circuit die by the composite bonding layer through dielectric-to-dielectric bonding.

8. The semiconductor device of claim 7 further comprising:
conductive vias extending through the composite bonding layer, wherein the second integrated circuit die is further bonded to the first integrated circuit die by the conductive vias through metal-to-metal bonding.

9. The semiconductor device of claim 7 further comprising:
an encapsulant around the first semiconductor component; and
a redistribution structure electrically connected to the first semiconductor component, wherein the composite bonding layer extends from a surface of the redistribution structure to the first semiconductor component.

10. The semiconductor device of claim 1, wherein the dielectric stress buffer material comprises sp² hybridization atoms, and wherein the dielectric planarization material comprises sp³ hybridization atoms.

11. A semiconductor package comprising:
a semiconductor component;
an encapsulant around the semiconductor component
a redistribution structure electrically on the encapsulant and extending laterally from sidewalls of the semiconductor component, wherein the redistribution structure is electrically connected to the semiconductor component; and
a composite material between lateral surfaces of the semiconductor component and the redistribution structure, wherein the composite material comprises:
a first dielectric material interfacing the semiconductor component; and
a second dielectric material interfacing the redistribution structure, wherein a hardness of the second dielectric material is less than a hardness of the first dielectric material.

12. The semiconductor package of claim 11, wherein the semiconductor component is an interconnect die that electrically connects a first integrated circuit die to a second integrated circuit die, wherein the first integrated circuit die and the second integrated circuit die are disposed on an opposing side of the encapsulant as the redistribution structure.

13. The semiconductor package of claim 12 further comprising first conductive vias and second conductive vias extending through the encapsulant, wherein the first conductive vias electrically connect the first integrated circuit die to the redistribution structure, and wherein the second conductive vias electrically connect the second integrated circuit die to the redistribution structure.

14. The semiconductor package of claim 11, wherein a ratio of the hardness of the first dielectric material to the hardness of the second dielectric material is in a range of 10:7 to 10:8.

15. The semiconductor package of claim 11 further comprising third conductive vias extending through the composite material, wherein the third conductive vias electrically connects the redistribution structure to the semiconductor component.

16. The semiconductor package of claim 11, wherein the semiconductor component is a passive device die.

17. A method comprising:
depositing a composite bonding layer over a first semiconductor component, wherein the composite bonding layer comprises:
a dielectric stress buffer layer; and
a first dielectric planarization layer, wherein a hardness of the dielectric stress buffer layer is greater than a hardness of the first dielectric planarization layer;
performing a planarization process on the first dielectric planarization layer;
bonding a carrier substrate to the first semiconductor component by directly bonding the composite bonding layer to a first insulating bonding layer on the carrier substrate with insulator-to-insulator bonding;
forming an encapsulant around the first semiconductor component over the carrier substrate;
removing the carrier substrate to expose the composite bonding layer; and
forming a redistribution structure on the encapsulant and the component bonding layer, wherein the redistribution structure is electrically connected to the first semiconductor component.

18. The method of claim 17, wherein the redistribution structure is electrically connected to the first semiconductor component by conductive features extending through the composite bonding layer.

19. The method of claim 17, wherein depositing the composite bonding layer comprises depositing the first dielectric planarization layer at a lower temperature than the dielectric stress buffer layer.

20. The method of claim 17, wherein the dielectric stress buffer layer comprises:
a base layer, and
an interfacial layer between the base layer and the first dielectric planarization layer, wherein a hardness of the interfacial layer is greater than the hardness of the first dielectric planarization layer and less than a hardness of the base layer.
